(19) United States
(12) Patent Application Publication
(10) Pub. No.: US 2007/0066051 A1
(43) Pub. Date: Mar. 22, 2007

(54) Method for forming gate pattern for electronic device

(75) Inventors: Szu-Hung Chen, Xinwu Shiang (TW); Chien-I Kuo, Meishan Shiang (TW); Edward Yi Chang, Hsinchu City (TW)

Correspondence Address: BRUCE H. TROXELL, SUITE 1404, 5205 LEESBURG PIKE, FALLS CHURCH, VA, 22041, US

(73) Assignee: National Chiao Tung University

(21) Appl. No.: 11/291,852

(22) Filed: Dec. 2, 2005

(30) Foreign Application Priority Data
Sep. 16, 2005 (TW) 094131980

(51) Int. Cl. H01L 21/4763

(52) U.S. Cl. 438/626; 438/631

(57) ABSTRACT

A method for forming a gate pattern for an electronic device, comprising steps of: providing a substrate, whereon a first photo-resist layer is formed; performing a first photo-lithography process so as to form a first pattern with a first width on the substrate; forming a second photo-resist layer, covering the first pattern and the first photo-resist layer on the substrate; and performing a second photo-lithography process, which is shifted from the first photo-lithography process, so as to form a second pattern with a second width on the substrate; wherein the second width is smaller than the first width.

### BACKGROUND OF THE INVENTION

1. Field of the Invention

The present invention generally relates to a method for forming a gate pattern for an electronic device and, more particularly, to a method using two-step exposure with a single mask for forming a gate pattern with deep sub-micron or nano-meter scale resolution.

2. Description of the Prior Art

In recent years, microwave semiconductor devices have played an important role in high-frequency communication applications. More particularly, field-effect transistors (FET's), also referred to as uni-polar transistors, are suitable for use in low-noise amplifiers due to the advantageous characteristics such as low noise and low power-consumption. The high-frequency characteristics of the FET's strongly depend on reduction of the gate length. Therefore, lots of efforts have been made on gate length reduction.

In U.S. Pat. No. 6,605,411, Nakao provides a two-step exposure technology so as to obtain a semiconductor device pattern, as described with reference to FIG. 1A to FIG. 1D. In FIG. 1A, a substrate 11 is provided, on which are formed in turn an insulating layer 12, a conductive layer 13 and a first photo-resist layer 14. A first mask (not shown) is used to perform a first photo-lithography process to form a pattern 14a in the first photo-resist layer 14. After the first photo-resist layer 14 is removed, a pattern 11a is formed on the substrate 11, as shown in FIG. 1B. After a second photo-resist layer 15 is formed by spin-coating, a second mask (not shown) is used to perform a second photo-lithography process to form a cross-sectional structure as shown in FIG. 1C. Afterwards, the conductive layer 13, the insulating layer 12 and the second photo-resist layer 15 are removed in turn so as to form a pattern 13a, as shown in FIG. 1D. However, the afore-mentioned prior art suffers from complexity and difficulty in using two different masks.

Moreover, in U.S. Pat. No. 6,596,646, Andideh et al provide a method for forming a fine gate pattern using lateral etching. As shown in FIG. 2A, a substrate 21 is provided, on which are formed in turn an insulating layer 22, a blocking layer 23 and a photo-resist layer 24. A mask (not shown) is used to perform a photo-lithography process to form a pattern with a width W in the photo-resist layer 24. The un-covered portion of the blocking layer 23 is removed by etching so as to form a cross-sectional structure as shown in FIG. 2B. After the photo-resist layer 24 is removed, a pattern with a reduced width W′ is obtained using wet etching to etch away both the surface and the side walls of the blocking layer 23, as shown in FIG. 2C. The pattern with a reduced width W′ is transferred from the blocking layer 23 to the insulating layer 22 so as to form a gate pattern smaller than the resolution of the utilized exposure system, as shown in FIG. 2D. However, this prior art method is useful only in mesa pattern formation and cannot be applied in trench pattern formation.

Even though researchers in both the industry and the academy have made lots of efforts in phase-shift masks and other advanced exposure systems, it results in higher cost in chip manufacture.

Therefore, there is need in providing a method for forming a gate pattern for an electronic device, achieving higher resolution of the photo-lithography process using a conventional exposure system so as to reduce the manufacture cost.

### SUMMARY OF THE INVENTION

It is the primary object of the present invention to provide a method for forming a gate pattern for an electronic device, achieving a gate pattern of deep sub-micron or nano-meter scale resolution using two-step exposure with a single mask so as to reduce the manufacture cost.

It is a secondary object of the present invention to provide a method for forming a gate for an electronic device, achieving a gate of deep sub-micron or nano-meter scale resolution using two-step exposure with a single mask for nano-electronics applications.

In order to achieve the foregoing objects, the present invention provides a method for forming a gate pattern for an electronic device, comprising steps of: providing a substrate, on the substrate being formed a first photo-resist layer; performing a first photo-lithography process, so as to form a first pattern with a first width on the substrate; forming a second photo-resist layer, covering the first pattern and the first photo-resist layer on the substrate; and performing a second photo-lithography process shifted from the first photo-lithography process, so as to form a second pattern with a second width on the substrate; wherein the second width is smaller than the first width.

The present invention further provides a method for forming a gate pattern for an electronic device, comprising steps of: providing a substrate, on the substrate being formed a dielectric layer and a first photo-resist layer in turn; performing a first photo-lithography process, so as to form a first pattern with a first width on the dielectric layer; transferring the first pattern to the substrate, so as to form a second pattern in the dielectric layer; forming a second photo-resist layer, covering the second pattern and the dielectric layer on the substrate; and performing a second photo-lithography process shifted from the first photo-lithography process, so as to form a third pattern with a second width on the substrate; wherein the second width is smaller than the first width.

The present invention provides a method for forming a gate electrode for an electronic device, comprising steps of: providing a substrate, on the substrate being formed a first photo-resist layer; performing a first photo-lithography process, so as to form a first pattern with a first width on the substrate; forming a second photo-resist layer, covering the first pattern and the first photo-resist layer on the substrate; forming a third photo-resist layer on the second photo-resist layer; performing a second photo-lithography process shifted from the first photo-lithography process, so as to form a second pattern with a second width on the substrate; and forming a conductive layer electrically connected to the substrate; wherein the second width is smaller than the first width.

The present invention further provides a method for forming a gate electrode for an electronic device, comprising steps of: providing a substrate, on the substrate being formed a dielectric layer and a first photo-resist layer in turn; performing a first photo-lithography process, so as to form a first pattern with a first width on the dielectric layer; transferring the first pattern to the substrate, so as to form a second pattern in the dielectric layer; forming a second photo-resist layer, covering the second pattern and the dielectric layer on the substrate; and forming a third photo-resist layer on the second photo-resist layer; performing a second photo-lithography process shifted from the first photo-lithography process, so as to form a third pattern with a second width on the substrate; and forming a conductive layer electrically connected to the substrate; wherein the second width is smaller than the first width.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms.

### BRIEF DESCRIPTION OF THE DRAWINGS

The objects, spirits and advantages of the preferred embodiment of the present invention will be readily understood by the accompanying drawings and detailed descriptions:

FIG. 1A to FIG. 1D are schematic diagrams showing steps in a conventional method for forming a gate pattern for an electronic device according to the prior art;

FIG. 2A to FIG. 2D are schematic diagrams showing steps in another conventional method for forming a gate pattern for an electronic device according to the prior art;

FIG. 3A to FIG. 3C are schematic diagrams showing steps in a method for forming a gate pattern for an electronic device according to the present invention;

FIG. 4A to FIG. 4D are schematic diagrams showing steps in another method for forming a gate pattern for an electronic device according to the present invention;

FIG. 5A to FIG. 5D are schematic diagrams showing steps in a method for forming a gate electrode for an electronic device according to the present invention; and

FIG. 6A to FIG. 6E are schematic diagrams showing steps in another method for forming a gate electrode for an electronic device according to the present invention.

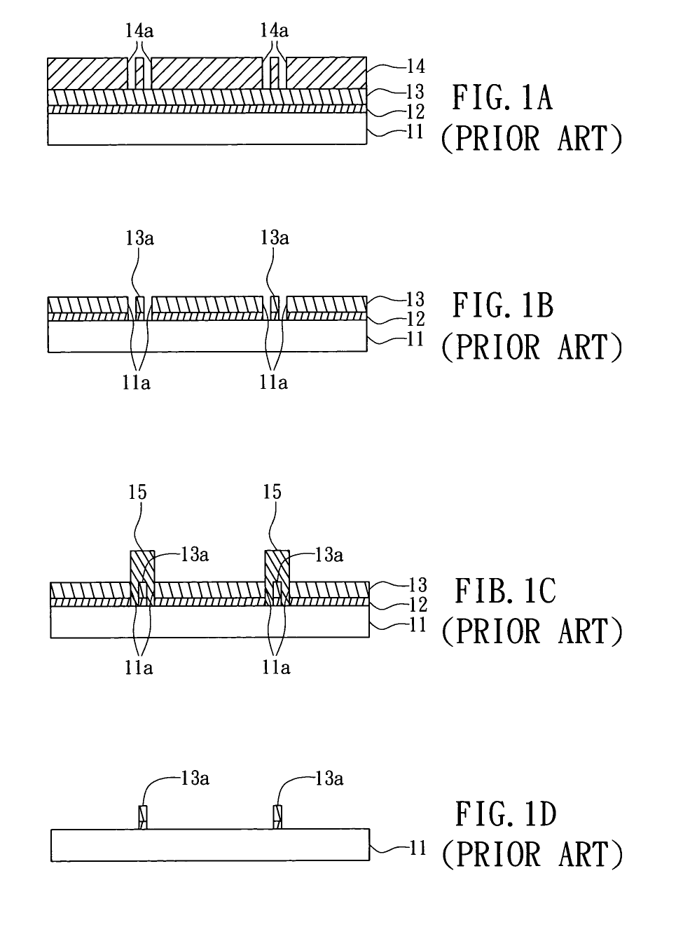

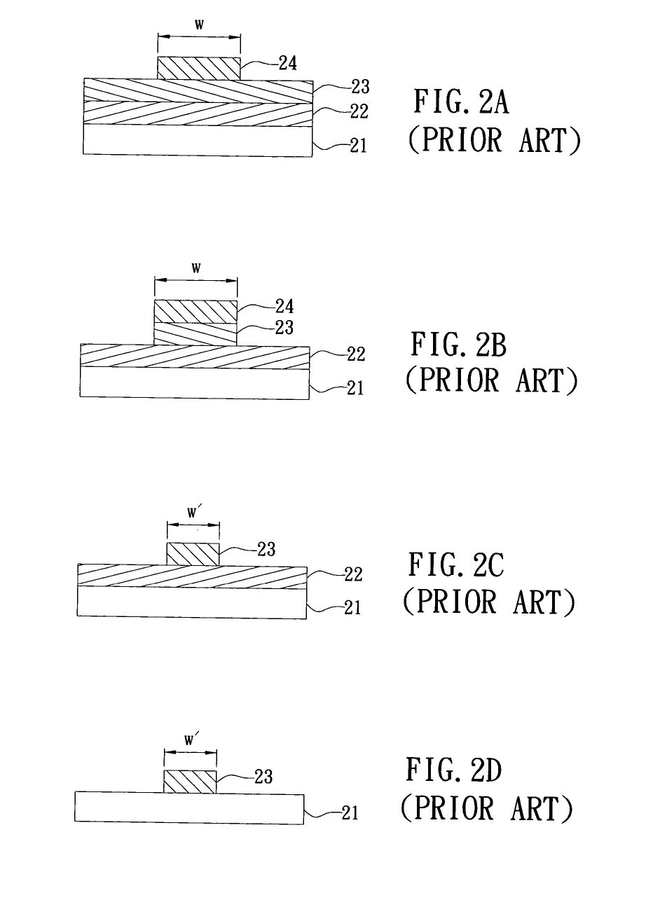

### DETAILED DESCRIPTION OF THE INVENTION

The present invention providing a method for forming a gate pattern for an electronic device can be exemplified by the preferred embodiments as described hereinafter.

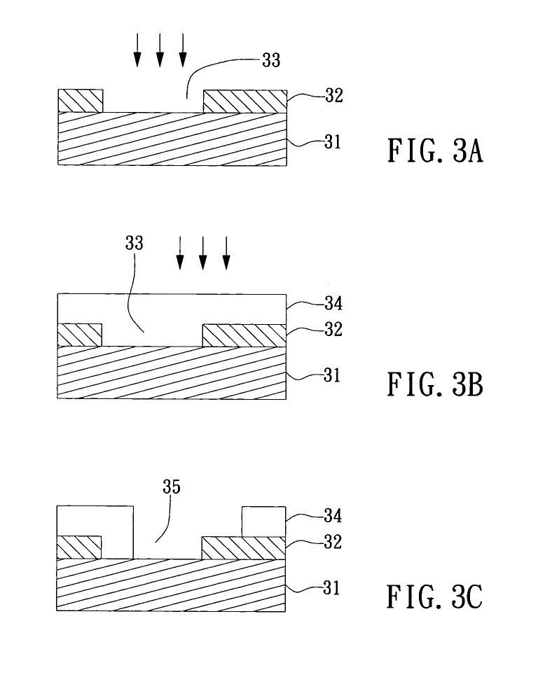

FIG. 3A to FIG. 3C are schematic diagrams showing steps in a method for forming a gate pattern for an electronic device according to the present invention. First, a substrate 31 is provided, on which is formed a first photo-resist layer 32. A first photo-lithography process is performed to form a first pattern 33 with a first width on the substrate 31, as shown in FIG. 3A. Then, a second photo-resist layer 34 is formed covering the first pattern 33 and the first photo-resist layer 32 on the substrate 31, as shown in FIG. 3B. Afterwards, a second photo-lithography process shifted from the first photo-lithography process is performed, so as to form a second pattern 35 with a second width on the substrate 31, as shown in FIG. 3C. The second width is smaller than the first width.

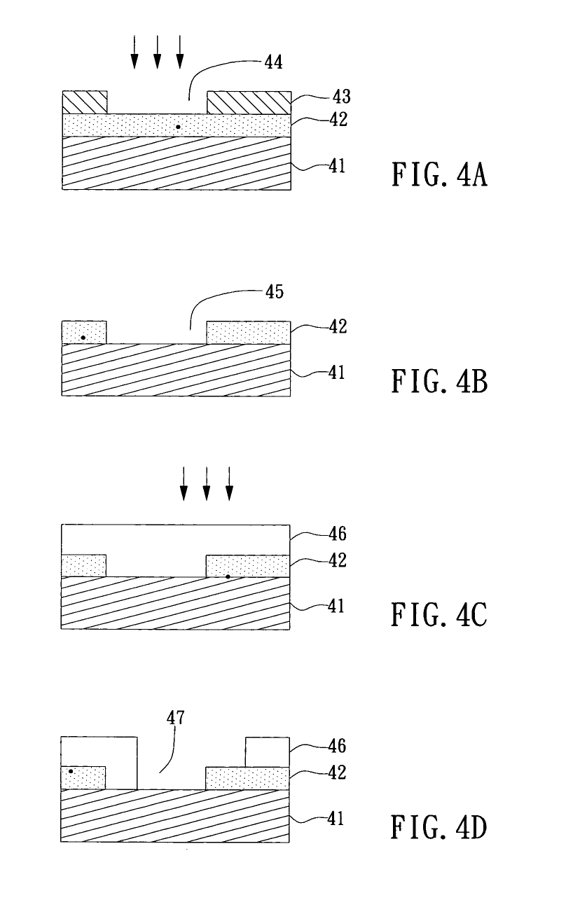

FIG. 4A to FIG. 4D are schematic diagrams showing steps in another method for forming a gate pattern for an electronic device according to the present invention. First, a substrate 41 is provided, on which are formed a dielectric layer 42 and a first photo-resist layer 43 in turn. A first photo-lithography process is performed to form a first pattern 44 with a first width on the dielectric layer 42, as shown in FIG. 4A. Then, the first pattern 44 is transferred to the substrate 41 by etching so as to form a second pattern 45 in the dielectric layer 42, as shown in FIG. 4B. A second photo-resist layer 46 is formed covering the second pattern 45 and the dielectric layer 42 on the substrate 41, as shown in FIG. 4C. Afterwards, a second photo-lithography process shifted from the first photo-lithography process is performed, so as to form a third pattern 47 with a second width on the substrate 41, as shown in FIG. 4D. The second width is smaller than the first width.

Using the afore-mentioned methods of the present invention, the resolution of the conventionally used I-line stepper can be improved. More particularly, the methods disclosed in the present invention are applicable to the manufacture of field-effect transistors with a gate electrode. Preferably, the substrate is a semiconductor substrate. Preferably, the dielectric layer is an oxide layer or a nitride layer.

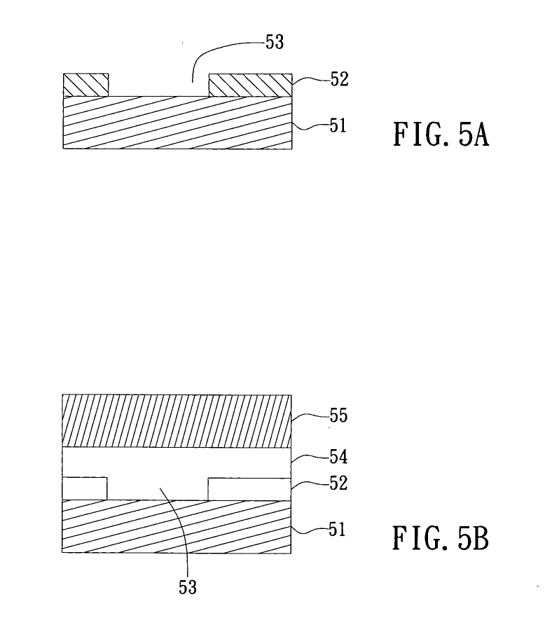

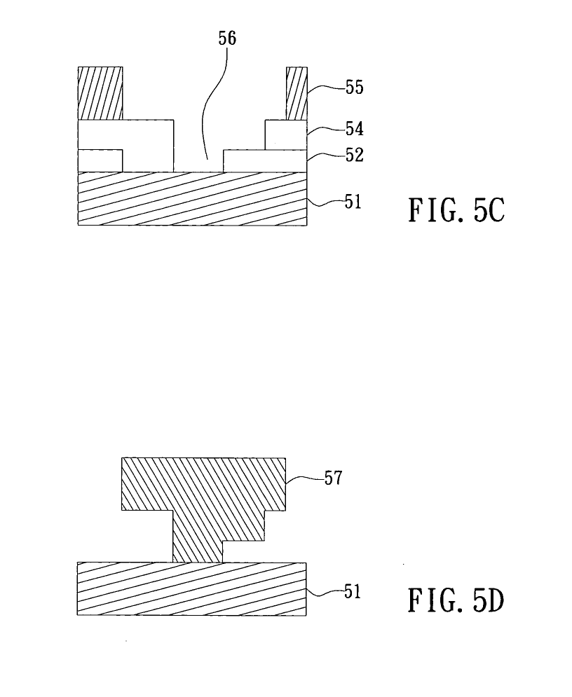

Moreover, FIG. 5A to FIG. 5D are schematic diagrams showing steps in a method for forming a gate electrode for an electronic device according to the present invention. First, a substrate 51 is provided, on which is formed a first photo-resist layer 52. A first photo-lithography process is performed to form a first pattern 53 with a first width on the substrate 51, as shown in FIG. 5A. Then, a second photo-resist layer 54 is formed covering the first pattern 53 and the first photo-resist layer 52 on the substrate 51, and a third photo-resist layer 55 is formed on the second photo-resist layer 54, as shown in FIG. 5B. A second photo-lithography process shifted from the first photo-lithography process is performed, so as to form a second pattern 56 with a second width on the substrate 51, as shown in FIG. 5C. Then, a conductive layer 57 is formed electrically connected to the substrate 51. At last, the first photo-resist layer 52, the second photo-resist layer 54 and the third photo-resist layer 55 are removed, as shown in FIG. 5D. The second width is smaller than the first width.

In the foregoing embodiment, a T-gate electrode is formed after the first photo-resist layer 52, the second photo-resist layer 54 and the third photo-resist layer 55 are removed. Therefore, the present invention can be used to manufacture field-effect transistors with a deep sub-micron or a nano-meter gate electrode without using phase-shift mask (PSM) or other expensive and advanced exposure equipments.

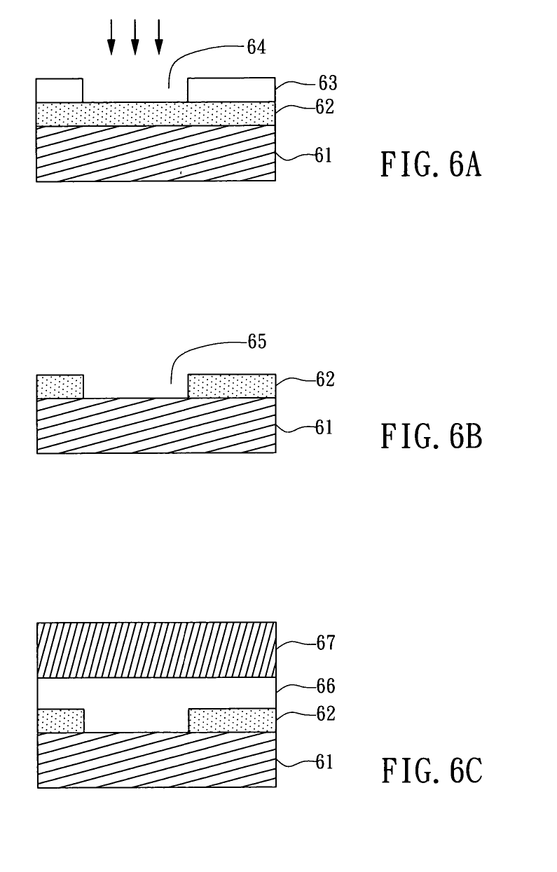

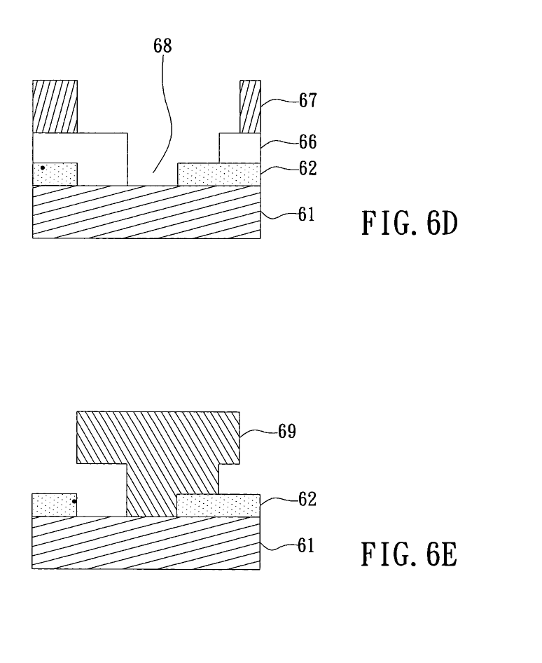

FIG. 6A to FIG. 6E are schematic diagrams showing steps in another method for forming a gate electrode for an electronic device according to the present invention. First, a substrate 61 is provided, on which are formed a dielectric layer 62 and a first photo-resist layer 63 in turn. A first photo-lithography process is performed to form a first pattern 64 with a first width on the dielectric layer 62, as shown in FIG. 6A. Then, the first pattern 64 is transferred to the substrate 61 by etching so as to form a second pattern 65 in the dielectric layer 62, as shown in FIG. 6B. A second photo-resist layer 66 is formed covering the second pattern 65 and the dielectric layer 62 on the substrate 61, and a third photo-resist layer 67 is formed on the second photo-resist layer 66, as shown in FIG. 6C. A second photo-lithography process shifted from the first photo-lithography process is performed, so as to form a third pattern 68 with a second width on the substrate 61, as shown in FIG. 6D. Then, a conductive layer 69 is formed electrically connected to the substrate 61. At last, the second photo-resist layer 66 and the third photo-resist layer 67 are removed, as shown in FIG. 6E. The second width is smaller than the first width.

In the foregoing embodiment, a T-gate electrode is formed after the second photo-resist layer 66 and the third photo-resist layer 67 are removed. Therefore, the present invention can be used to manufacture field-effect transistors with a deep sub-micron or a nano-meter gate electrode without using phase-shift mask (PSM) or other expensive and advanced exposure equipments.

Accordingly, the present invention discloses a method for forming a gate pattern for an electronic device, achieving a gate pattern of deep sub-micron or nano-meter scale resolution using two-step exposure with a single mask so as to reduce the manufacture cost. Therefore, the present invention has been examined to be new, non-obvious and useful.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A method for forming a gate pattern for an electronic device, comprising steps of:
providing a substrate, on said substrate being formed a first photo-resist layer;
performing a first photo-lithography process, so as to form a first pattern with a first width on said substrate;
forming a second photo-resist layer, covering said first pattern and said first photo-resist layer on said substrate; and
performing a second photo-lithography process shifted from said first photo-lithography process, so as to form a second pattern with a second width on said substrate;
wherein said second width is smaller than said first width.

2. The method as recited in claim 1, wherein said electronic device is a field-effect transistor.

3. The method as recited in claim 1, wherein said substrate is a semiconductor substrate.

4. The method as recited in claim 1, wherein said second pattern is said gate pattern.

5. A method for forming a gate pattern for an electronic device, comprising steps of:
providing a substrate, on said substrate being formed a dielectric layer and a first photo-resist layer in turn;
performing a first photo-lithography process, so as to form a first pattern with a first width on said dielectric layer;
transferring said first pattern to said substrate, so as to form a second pattern in said dielectric layer;
forming a second photo-resist layer, covering said second pattern and said dielectric layer on said substrate; and
performing a second photo-lithography process shifted from said first photo-lithography process, so as to form a third pattern with a second width on said substrate;
wherein said second width is smaller than said first width.

6. The method as recited in claim 5, wherein said electronic device is a field-effect transistor.

7. The method as recited in claim 5, wherein said substrate is a semiconductor substrate.

8. The method as recited in claim 5, wherein said second pattern is said gate pattern.

9. The method as recited in claim 5, wherein said dielectric layer is an oxide layer.

10. The method as recited in claim 5, wherein said dielectric layer is a nitride layer.

11. A method for forming a gate electrode for an electronic device, comprising steps of:
providing a substrate, on said substrate being formed a first photo-resist layer;
performing a first photo-lithography process, so as to form a first pattern with a first width on said substrate;
forming a second photo-resist layer, covering said first pattern and said first photo-resist layer on said substrate;
forming a third photo-resist layer on said second photo-resist layer;
performing a second photo-lithography process shifted from said first photo-lithography process, so as to form a second pattern with a second width on said substrate; and
forming a conductive layer electrically connected to said substrate;
wherein said second width is smaller than said first width.

12. The method as recited in claim 11, wherein said electronic device is a field-effect transistor.

13. The method as recited in claim 11, wherein said substrate is a semiconductor substrate.

14. The method as recited in claim 11, wherein said second pattern is a gate pattern.

15. A method for forming a gate electrode for an electronic device, comprising steps of:
providing a substrate, on said substrate being formed a dielectric layer and a first photo-resist layer in turn;
performing a first photo-lithography process, so as to form a first pattern with a first width on said dielectric layer;
transferring said first pattern to said substrate, so as to form a second pattern in said dielectric layer;
forming a second photo-resist layer, covering said second pattern and said dielectric layer on said substrate; and
forming a third photo-resist layer on said second photo-resist layer;
performing a second photo-lithography process shifted from said first photo-lithography process, so as to form a third pattern with a second width on said substrate; and
forming a conductive layer electrically connected to said substrate;
wherein said second width is smaller than said first width.

16. The method as recited in claim 15, wherein said electronic device is a field-effect transistor.

17. The method as recited in claim 15, wherein said substrate is a semiconductor substrate.

18. The method as recited in claim 15, wherein said third pattern is said gate pattern.

19. The method as recited in claim 15, wherein said dielectric layer is an oxide layer.

20. The method as recited in claim 15, wherein said dielectric layer is a nitride layer.
